(19) United States
(12) Patent Application Publication
(10) Pub. No.: US 2024/0203967 A1
(43) Pub. Date: Jun. 20, 2024

(54) DISPLAY DEVICE

(71) Applicant: LG DISPLAY CO., LTD., SEOUL (KR)

(72) Inventors: ByungHyun LEE, Paju-si (KR); SunHwa LEE, Goyang-si (KR); JongBeom LEE, Paju-si (KR); Soyi LEE, Paju-si (KR); Seeun KIM, Seoul (KR)

(73) Assignee: LG DISPLAY CO., LTD., SEOUL (KR)

(21) Appl. No.: 18/369,278

(22) Filed: Sep. 18, 2023

(30) Foreign Application Priority Data
Dec. 16, 2022 (KR) 10-2022-0176818

(51) Int. Cl. H01L 25/16; H01L 23/538; H01L 23/60

(52) U.S. Cl. CPC H01L 25/167; H01L 23/5386; H01L 23/60; H01L 24/32

(57) ABSTRACT

A display device includes a lower substrate which includes an active area, a first non-active area on both sides of the active area, a second non-active area above the active area, and a third non-active area on both sides of the second non-active areas; a plurality of plate patterns disposed in the active area, the first non-active area, the second non-active area, and the third non-active area; and a plurality of line patterns which is disposed between the plurality of plate patterns in the active area, the first non-active area, and the second non-active area; and a plurality of link lines disposed on the plurality of plate patterns in the second non-active area.

### CROSS-REFERENCE TO RELATED APPLICATION

This application claims the priority of Korean Patent Application No. 10-2022-0176818 filed on Dec. 16, 2022, which is hereby incorporated by reference in its entirety.

### BACKGROUND

### Field of the Disclosure

The present disclosure relates to a display device, and more particularly to, a stretchable display device which gives stretchability to a non-active area.

### Description of the Background

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material to be stretchable in a specific direction and changed in various forms is getting attention as a next generation display device.

### SUMMARY

Accordingly, the present disclosure is directed to a display device that substantially obviates one or more of problems due to limitations and disadvantages described above.

More specifically, the present disclosure is to provide a display device in which an area in which a plurality of link lines is disposed is formed as a stretching area.

The present disclosure is also to provide a display device in which a damage of a plurality of link lines due to a laser lift off (“LLO”) process is minimized.

The present disclosure is also to provide a display device which gives a stretchability to a non-active area.

Further, the present disclosure is to provide a display device which reduces a shrinkage rate difference between an active area and a non-active area.

The present disclosure is not limited to the above-mentioned and other features, which are not mentioned above, may be clearly understood by those skilled in the art from the following descriptions.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a lower substrate which includes an active area, a first non-active area on both sides of the active area, a second non-active area above the active area, and a third non-active area on both sides of the second non-active areas; a plurality of plate patterns disposed in the active area, the first non-active area, the second non-active area, and the third non-active area; and a plurality of line patterns which is disposed between the plurality of plate patterns in the active area, the first non-active area, and the second non-active area; and a plurality of link lines disposed on the plurality of plate patterns in the second non-active area. Accordingly, in the second non-active area in which the plurality of link lines is disposed, the plate pattern and the line patterns are formed together to ensure the stretchability of the second non-active area and reduce the damage of the plurality of link lines.

Other detailed matters of the exemplary aspects are included in the detailed description and the drawings.

According to the present disclosure, the plurality of link lines is formed in a non-active area having a stretchability to minimize a damage of the plurality of link lines during the LLO process.

According to the present disclosure, a plurality of link lines is disposed together to ensure a stretching area between link lines.

According to the present disclosure, a difference in a stretching rage of the active area and the non-active area is minimized.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is a schematic plan view of an active area and a first non-active area of a display device according to an exemplary aspect of the present disclosure;

FIG. 3 is an enlarged plan view of an active area of a display device according to an exemplary aspect of the present disclosure;

FIG. 4 is a cross-sectional view taken along IV-IV′ of FIG. 3;

FIG. 5 is a cross-sectional view taken along line V-V′ of FIG. 3;

FIG. 6 is a cross-sectional view taken along line VI-VI′ of FIG. 3;

FIG. 7 is a schematic plan view of a second non-active area and a third non-active area of a display device according to an exemplary aspect of the present disclosure;

FIG. 8 is a schematic plan view of a link line of a display device according to an exemplary aspect of the present disclosure;

FIG. 9A is an enlarged plan view of an area A of FIG. 7;

FIG. 9B is a cross-sectional view taken along IXb-IXb′ of FIG. 9A;

FIG. 10A is an enlarged plan view of an area B of FIG. 7;

FIG. 10B is a cross-sectional view of a display device taken along Xb-Xb′ of FIG. 10A;

FIG. 10C is a cross-sectional view taken along line Xc-Xc′ of FIG. 10A;

FIG. 11 is a schematic plan view of a third non-active area of a display device according to an exemplary aspect of the present disclosure;

FIG. 12 is a schematic diagram of a high potential power link line, a low potential power link line, and an LOG line of a display device according to an exemplary aspect of the present disclosure;

FIG. 13A is a cross-sectional view taken along line XIIIa-XIIIa′ of FIG. 11;

FIG. 13B is a cross-sectional view taken along line XIIIb-XIIIb′ of FIG. 12.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a display device according to exemplary aspects of the present disclosure will be described in detail with reference to accompanying drawings.

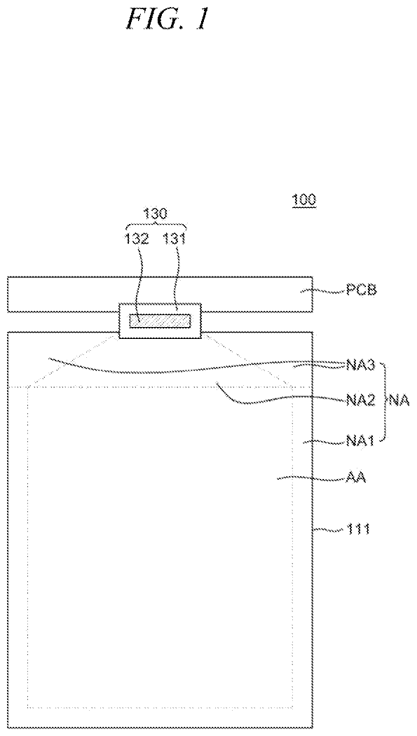

FIG. 1 is a plan view of a display device according to an exemplary aspect of the present disclosure. For the convenience of description, in FIG. 1, among various components of the display device 100, only a lower substrate 111, a flexible film 130, and a printed circuit boards PCB are illustrated.

First, a display device 100 according to an exemplary aspect of the present disclosure is a display device 100 which is capable of displaying images even in a bent or extended state and is also referred to as a stretchable display device 100, a flexible display device 100, and an extendable display device 100. As compared with the general display device 100 of the related art, the display device 100 has not only a high flexibility, but also stretchability. Therefore, the user may bend or extend a display device 100 and a shape of a display device 100 may be freely changed in accordance with manipulation of a user. For example, when the user pulls the display device 100 by holding ends of the display device, the display device 100 may be extended to the pulling direction of the user. Alternatively, when the user disposes the display device 100 on an outer surface which is not flat, the display device 100 may be disposed to be bent in accordance with the shape of the outer surface. Further, when a force applied by the user is removed, the display device 100 may return to its original shape.

Referring to FIG. 1, the lower substrate 111 is a substrate which supports and protects several components of the display device 100. The lower substrate 111 may have an active area AA and a non-active area NA enclosing the active area AA. However, the active area AA and the non-active area NA are not mentioned to be limited to the lower substrate 111, but mentioned for the entire display device 100.

The active area AA is an area in which images are displayed in the display device 100 and a plurality of pixels PX is disposed in the active area AA. Each pixel PX may include a display element and various driving elements for driving the display element. Various driving elements may refer to at least one thin film transistor (TFT) and a capacitor, but are not limited thereto. The plurality of pixels PX may be connected to various wiring lines to be driven, respectively. For example, each of the plurality of pixels PX may be connected to various wiring lines, such as a gate line, a data line, a high potential voltage line, a low potential voltage line, a reference voltage line, and an initialization voltage line.

The non-active area NA is an area where no image is displayed. The non-active area NA is an area adjacent to the active area AA. The non-active area NA is adjacent to the active area AA to enclose the active area AA. However, it is not limited thereto so that the non-active area NA corresponds to an area excluding the active area AA from the lower substrate 111 and may be modified and separated in various forms. In the non-active area NA, various components for driving a plurality of pixels PX disposed in the active area AA, such as a gate driver GD and a power supply PS, may be disposed. In the non-active area NA, a plurality of pads connected to the flexible film 130 and the printed circuit board PCB may be disposed and each pad may be connected to each of the plurality of pixels PX of the active area AA.

The non-active area NA includes a first non-active area NA1, a second non-active area NA2, and a third non-active area NA3.

The first non-active area NA1 is a non-active area NA at the left side of the active area AA, a non-active area NA at the right side, and a non-active area NA on a lower side. The first non-active area NA1 may be an area in which the gate driver GD and the power supply PS are disposed.

The second non-active area NA2 corresponds to a part of the non-active area NA at an upper side of the active area AA. The second non-active area NA2 is a non-active area NA in which a plurality of pads connected to the flexible film 130 and a plurality of link lines LL which transmits a signal to the active area AA from the plurality of pads are disposed. The second non-active area NA2 is an area between a plurality of pads from an upper edge of the active area AA and is widened toward the active area AA from the plurality of pads. The second non-active area NA2 may radially expand with respect to the plurality of pads.

The third non-active area NA3 is a remaining area excluding the second non-active area NA2 from the non-active area NA on the upper side of the active area AA. The third non-active area NA3 is disposed on both sides of the second non-active area NA2. The third non-active area NA3 is an area in which a power link line LL including a low potential power link line VSSL and a high potential power link line VDDL and a plurality of line on glass (LOG) line are disposed.

The flexible film 130 is a film in which various components are disposed on a base film 131 having a flexibility and supplies signals to the plurality of sub pixels of the active area AA. The flexible film 130 is bonded to the plurality of pads disposed in the second non-active area NA2 and supplies various signals to the plurality of sub pixels SPX of the active area AA through the pad and the plurality of link lines LL. The flexible film 130 includes a base film 131 and a driver IC 132. Further, various components may be additionally disposed on the flexible film 110.

The base film 131 is a layer which supports the driving IC 132 of the flexible film 130. The base film 131 may be formed of an insulating material, and for example, may be formed of an insulating material having a flexibility.

The driving IC 132 is a component which processes data for displaying images and a driving signal for processing the image. In FIG. 1, even though it is illustrated that the driving IC 132 is mounted by the COF 130 technique, it is not limited thereto and the driving IC may be mounted by a technique such as chip on glass (COG) or tape carrier package (TCP).

The printed circuit board PCB connected to the flexible film 130 is disposed. A control unit, such as an IC chip or a circuit unit, may be mounted on the printed circuit board PCB. Further, on the printed circuit board PCB, a memory or a processor may also be mounted. The printed circuit board PCB is a configuration which generates a signal for driving a pixel PX to transmit the signal to the pixel PX.

Even though in FIG. 1, it is described that one flexible film 130 and one printed circuit board PCB are used, the number and the placement of the flexible film 130 and the printed circuit boards PCB are not limited thereto.

In the meantime, as described above, the display device 100 according to the exemplary aspect of the present disclosure is a stretchable display device 100 having a stretchability. To ensure the stretchability of the display device 100, the lower substrate 111 is formed as a flexible substrate and a configuration, such as a pixel PX, a gate driver GD, a power supply PS, or various lines formed on the lower substrate 111, is formed on the pattern layer 120 to ensure the stretchability of the display device 100.

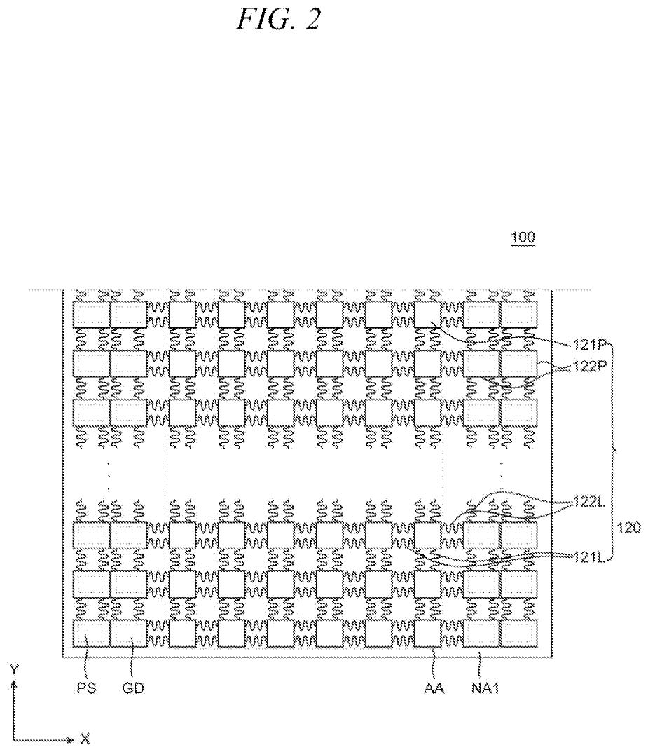

Hereinafter, referring to FIGS. 2 to 6, an active area AA and a first non-active area NA1 having a stretchability by the pattern layer 120 will be described in detail first.

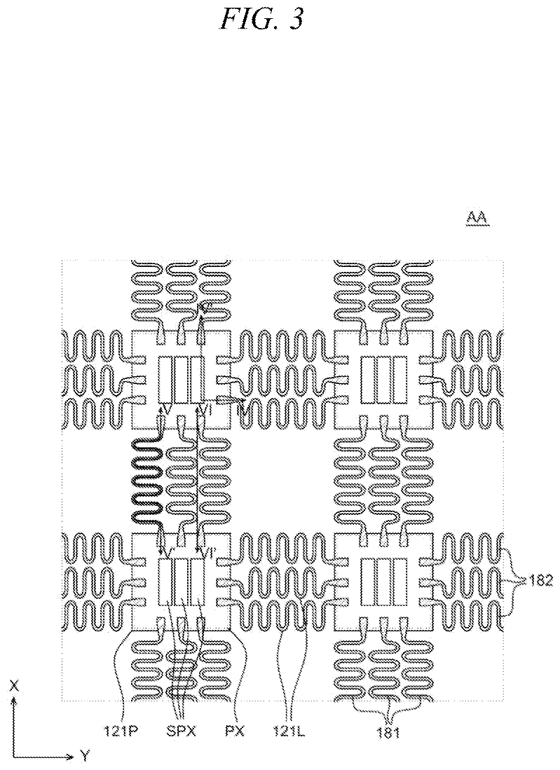

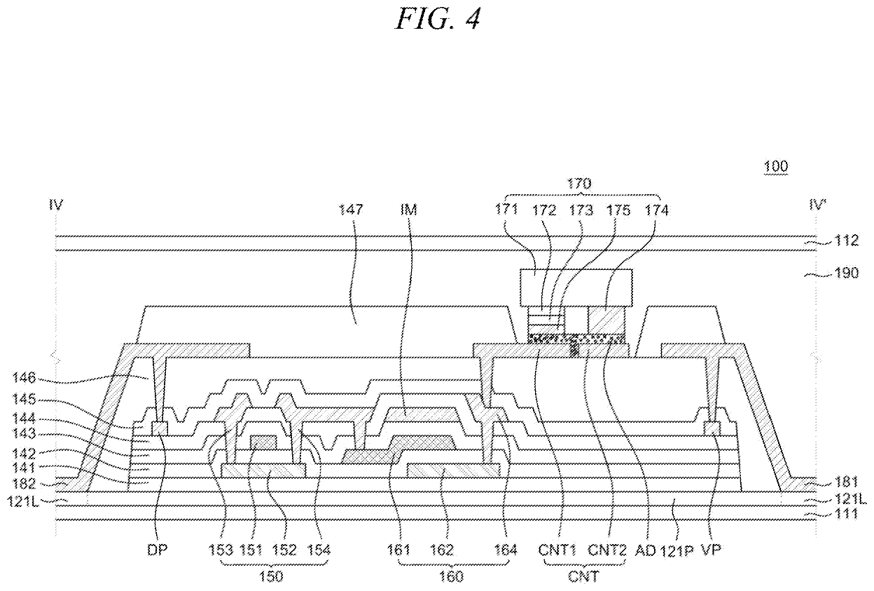

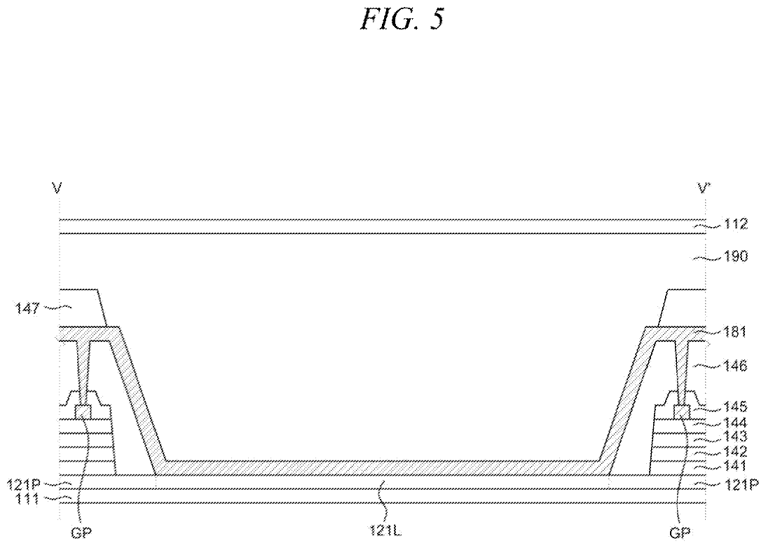

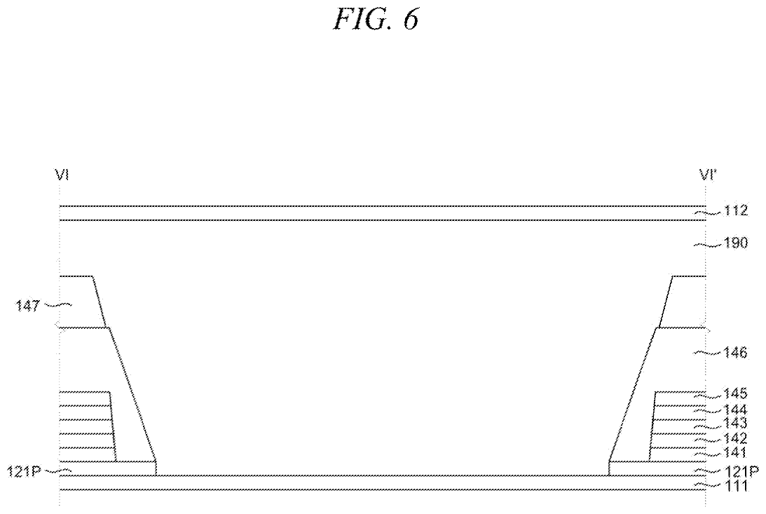

FIG. 2 is a schematic plan view of an active area and a first non-active area of a display device according to an exemplary aspect of the present disclosure. FIG. 3 is an enlarged plan view of an active area of a display device according to an exemplary aspect of the present disclosure. FIG. 4 is a cross-sectional view taken along IV-IV′ of FIG. 3. FIG. 5 is a cross-sectional view taken along line V-V′ of FIG. 3. FIG. 6 is a cross-sectional view taken along line VI-VI′ of FIG. 3.

Referring to FIGS. 2 to 4, a display device 100 according to an exemplary aspect of the present disclosure includes a lower substrate 111, a pattern layer 120, a plurality of pixels PX, a gate driver GD, a data driver, a power supply PS, a filling layer 190, and an upper substrate 112.

The upper substrate 112 is disposed on the lower substrate 111. The lower substrate 111 is a substrate which supports the pattern layer 120 on which the pixels PX, the gate driver GD, and the power supply PS are formed. The upper substrate 112 is a substrate which covers and protects several components of the display device 100. The upper substrate 112 covers the pixels PX, the gate driver GD, and the power supply PS.

The lower substrate 111 and the upper substrate 112 which are flexible substrates may be configured by an insulating material which is bendable or extendable. For example, the lower substrate 111 and the upper substrate 112 may be formed of a silicon rubber such as polydimethylsiloxane (PDMS) or an elastomer such as polyurethane (PU) or polytetrafluoroethylene (PTFE) and thus have a flexibility. Further, the materials of the lower substrate 111 and the upper substrate 112 may be the same, but are not limited thereto and may vary.

The lower substrate 111 and the upper substrate 112 are flexible substrates to be reversibly expandable and contractible. Accordingly, the lower substrate 111 may be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, or a first flexible substrate. The upper substrate 112 may be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, or a second flexible substrate.

Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a timing when an object to be stretched is broken or cracked. A thickness of the lower substrate 111 may be 10 um to 1 mm, but is not limited thereto.

Referring to FIGS. 2 and 3, the pattern layer 120 is disposed between the lower substrate 111 and the upper substrate 112. The pattern layer 120 may include a plurality of plate patterns and a plurality of line patterns. The pattern layer 120 may include a plurality of first plate patterns 121P and a plurality of first line patterns 121L disposed in the active area AA and a plurality of second plate patterns 122P and a plurality of second line patterns 122L disposed in the first non-active area NA1. Further, the pattern layer 120 includes a plurality of third plate patterns 123P disposed in the second non-active area NA2, a fourth plate pattern 124P disposed in the third non-active area NA3 and a plurality of third line patterns 123L disposed in the second non-active area NA2. Therefore, the plurality of plate patterns may include the plurality of first plate patterns 121P, the plurality of second plate patterns 122P, the plurality of third plate patterns 123P and the fourth plate pattern 124P. The plurality of line patterns may include the plurality of first line patterns 121L, the plurality of second line patterns 122L and the plurality of third line patterns 123L.

The plurality of first plate patterns 121P is disposed in the active area AA and the plurality of second plate patterns 122P is disposed in the first non-active area NA1. On the plurality of first plate patterns 121P, a plurality of pixels PX is formed and on the plurality of second plate patterns 122P, a gate driver GD and a power supply PS are formed.

The plurality of first plate patterns 121P and the plurality of second plate patterns 122P may be disposed in the form of separate islands. The plurality of first plate patterns 121P and the plurality of second plate patterns 122P may be individually separated. Therefore, the plurality of first plate patterns 121P and the plurality of second plate patterns 122P may be referred to as first island patterns and second island patterns or first individual patterns and second individual patterns.

A size of each of the plurality of second plate patterns 122P may be larger than a size of each of the plurality of first plate patterns 121P. In each of the plurality of second plate patterns 122P, one stage of the gate driver GD is disposed. Therefore, an area occupied by various circuit configurations which configure one stage of the gate driver GD may be relatively larger than an area occupied by one pixel PX so that a size of each of the plurality of second plate patterns 122P may be larger than a size of each of the plurality of first plate patterns 121P.

In the meantime, even though it is illustrated in FIG. 2 that the plurality of second plate patterns 122P is disposed in the first non-active areas NA1 on both sides of the active area AA in the first direction X, this is illustrative so that the plurality of second plate patterns 122P may be disposed in an arbitrary area of the non-active area NA. Further, even though it is illustrated that the plurality of first plate patterns 121P and the plurality of second plate patterns 122P have a square shape, it is not limited thereto and the shapes of the plurality of first plate patterns 121P and the plurality of second plate patterns 122P may vary in various forms.

In the active area AA, a plurality of first line patterns 121L is disposed between the plurality of first plate patterns 121P. The plurality of first line patterns 121L is patterns which connect first plate patterns 121P which are adjacent to each other and is referred to as internal connection patterns CNT. That is, the plurality of first line patterns 121L is disposed between the plurality of first plate patterns 121P. Some of the plurality of first line patterns 121L connects a plurality of first plate patterns 121P which is adjacent to each other in a first direction X and the other connects a plurality of first plate patterns 121P which is adjacent to each other in a second direction Y.

In the first non-active area NA1, the plurality of second line patterns 122L is disposed between the plurality of second plate patterns 122P and between the plurality of first plate patterns 121P and the plurality of second plate patterns 122P. The plurality of second line patterns 122L connects the first plate pattern 121P and the second plate pattern 122P which are adjacent to each other or connects a plurality of adjacent second plate patterns 122P and is referred to as external connection patterns CNT. The plurality of second line patterns 122L may be disposed between the first plate pattern 121P and the second plate pattern 122P which are adjacent to each other and between the plurality of second plate patterns 122P which is adjacent to each other. Some of the plurality of second line patterns 122L connects the plurality of second plate patterns 122P which is adjacent to each other in the first direction X or connects the first plate pattern 121P and the second plate pattern 122P which are adjacent to each other and the other connects the plurality of second plate patterns 122P in the second direction Y.

The plurality of first line patterns 121L and the plurality of second line patterns 122L have a wavy shape. For example, the plurality of first line patterns 121L and the plurality of second line patterns 122L have a sinusoidal shape. However, the shape of the plurality of first line patterns 121L and the plurality of second line patterns 122L is not limited thereto. For example, the plurality of first line patterns 121L and second line patterns 122L may extend in a zigzag pattern. Alternatively, the plurality of first line patterns 121L and the plurality of second line patterns 122L may have various shapes, such as a shape in which a plurality of rhombic substrates is connected at their vertexes to be extended or a shape in which semi-circular and quadrant-shaped substrates are connected to each other. Further, the number and the shape of the plurality of first line patterns 121L and the plurality of second line patterns 122L illustrated in FIG. 1 are examples and may be changed in various forms depending on the design.

Further, in the first non-active area NA1, similar to the active area AA, the plurality of second plate patterns 122P and the second plate patterns 122P are connected and the plurality of second line patterns 122L having the stretchability is disposed to be freely extended or bent. Therefore, the first non-active area NA1 has a stretchability together with the active area AA to be flexibly modified.

In the meantime, the plurality of first plate patterns 121P, the plurality of first line patterns 121L, the plurality of second plate patterns 122P, and the plurality of second line patterns 122L of the pattern layer 120 are rigid patterns. That is, the plurality of first plate patterns 121P, the plurality of first line patterns 121L, the plurality of second plate patterns 122P, and the plurality of second line patterns 122L may be more rigid than the lower substrate 111 and the upper substrate 112.

The plurality of first plate patterns 121P, the plurality of first line patterns 121L, the plurality of second plate patterns 122P, and the plurality of second line patterns 122L which are rigid substrates may be formed of a plastic material having a lower flexibility than the lower substrate 111 and the upper substrate 112. For example, the plurality of first plate patterns 121P, the plurality of first line patterns 121L, the plurality of second plate patterns 122P, and the plurality of second line patterns 122L may be formed of at least one material of polyimide (PI), polyacrylate, and polyacetate. At this time, when the plurality of first plate patterns 121P, the plurality of first line patterns 121L, the plurality of second plate patterns 122P, and the plurality of second line patterns 122L are formed of the same material, the plurality of first plate patterns 121P, the plurality of first line patterns 121L, the plurality of second plate patterns 122P, and the plurality of second line patterns 122L are integrally formed. However, when the plurality of first plate patterns 121P, the plurality of first line patterns 121L, the plurality of second plate patterns 122P, and the plurality of second line patterns 122L may be formed of different materials, but are not limited thereto.

Moduli of elasticity of the plurality of first plate patterns 121P, the plurality of first line patterns 121L, the plurality of second plate patterns 122P, and the plurality of second line patterns 122L may be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121P, the plurality of first line patterns 121L, the plurality of second plate patterns 122P, and the plurality of second line patterns 122L may be referred to as a plurality of first rigid patterns, a plurality of second rigid patterns, a plurality of third rigid patterns, and a plurality of fourth rigid patterns, respectively. Moduli of elasticity of the plurality of first plate patterns 121P, the plurality of first line patterns 121L, the plurality of second plate patterns 122P, and the plurality of second line patterns 122L may be 1000 times higher than the moduli of elasticity of the lower substrate 111 and the upper substrate 112, but it is not limited thereto.

In the meantime, in some exemplary aspects, the lower substrate 111 may be defined to include a plurality of first lower patterns and a second lower pattern. The plurality of first lower patterns may be an area of the lower substrate 111 overlapping the plurality of first plate patterns 121P and the plurality of second patterns 122P. The second lower pattern may be a remaining area which does not overlap the plurality of first plate patterns 121P and the plurality of second patterns 122P.

Further, the upper substrate 112 is defined to include a plurality of first upper patterns and a second upper pattern. The plurality of first upper patterns may be an area overlapping the plurality of the first plate patterns 121P and the plurality of second plate patterns 122P of the upper substrate 112, but the second upper pattern may be a remaining area which does not overlap the plurality of the first plate patterns 121P and the plurality of second plate patterns 122P.

At this time, moduli of elasticity of the plurality of first lower patterns and the first upper pattern may be higher than moduli of elasticity of the second lower pattern and the second upper pattern. For example, the plurality of first lower patterns and the first upper pattern may be formed of the same material as the plurality of first plate patterns 121P and the plurality of second plate patterns 122P. The second lower pattern and the second upper pattern may be formed of a material having a modulus of elasticity lower than those of the plurality of first plate patterns 121P and the plurality of second plate patterns 122P.

For example, the first lower pattern and the first upper pattern may be formed of polyimide (PI), polyacrylate, or polyacetate. Further, the second lower pattern and the second upper pattern may be formed of silicon rubber such as polydimethylsiloxane (PDMS) or elastomer such as polyurethane (PU) or polytetrafluoroethylene.

The gate driver GD is disposed on the plurality of second plate patterns 122P. The gate driver GD may be formed on the plurality of second plate patterns 122P in a gate in panel (GIP) manner when various elements on the plurality of first plate patterns 121P are manufactured. Therefore, various circuit configurations which configure the gate driver GD, such as transistors, capacitors, and wiring lines, may be disposed on the plurality of second plate patterns 122P. One stage which is a circuit which configures the gate driver GD and includes transistors and capacitors may be disposed above each of the plurality of second plate patterns 122P. However, the gate driver GD may be mounted in a chip on film (COF) manner, but is not limited thereto.

The power supply PS is disposed on the plurality of second plate patterns 122P. The power supply PS may be formed on the second plate pattern 122P adjacent to the gate driver GD. The power supply PS is a plurality of power blocks patterned when various components on the first plate pattern 121P is manufactured and may be formed on the second plate pattern 122P. The power supply PS is electrically connected to the gate driver GD of the first non-active area NA1 and the plurality of pixels PX of the active area AA to supply a driving voltage. For example, the power supply PS is electrically connected to the gate driver GD formed on the second plate pattern 122P and the plurality of pixels PX formed on the first plate patterns 121P through the second line pattern 122L and the first line pattern 121L. The power supply supplies a gate driving voltage to the gate driver GD and supplies a power voltage to each of the plurality of pixels PX.

Referring to FIG. 3, a pixel PX including the plurality of sub pixels SPX which is an individual unit emitting the light is disposed in the plurality of first plate patterns 121P. Each of the plurality of sub pixels SPX may include an LED 170 which is a display element and a driving transistor 160 and a switching transistor 150 which drive the LED 170. However, in the sub pixel SPX, the display element is not limited to an LED 170, and may also be changed to an organic light emitting diode. For example, the plurality of sub pixels SPX may include a red sub pixel, a green sub pixel, and a blue sub pixel, but is not limited thereto and colors of the plurality of sub pixels SPX may be modified to various colors as needed.

Hereinafter, a cross-sectional structure of the active area AA will be described in more detail with reference to FIGS. 4 to 6.

Referring to FIGS. 4 to 6, a plurality of inorganic insulating layers is disposed on the plurality of first plate patterns 121P. For example, a plurality of inorganic insulating layers may include a buffer layer 141, a gate insulating layer 142, a first interlayer insulating layer 143, a second interlayer insulating layer 144, and a passivation layer 145. However, in addition to the above-described inorganic insulating layer, another inorganic insulating layer may be additionally disposed or one or more of the above-described inorganic insulating layers may be omitted and a configuration of the plurality of inorganic insulating layers is not limited thereto.

First, the buffer layer 141 is disposed on the plurality of first plate patterns 121P. The buffer layer 141 is formed on the plurality of first plate patterns 121P to protect various components of the display device 100 from permeation of moisture and oxygen from the outside of the lower substrate 111 and the plurality of first plate patterns 121P. The buffer layer 141 may be configured by an insulating material. For example, the buffer layer 141 may be configured by a single layer or a double layer formed of at least one of silicon nitride (SiNx), silicon oxide (SiOx), and silicon oxynitride (SiON). However, the buffer layer 141 may be omitted depending on a structure or a characteristic of the display device 100.

At this time, the buffer layer 141 may be formed only in an area which overlaps the plurality of first plate patterns 121P and the plurality of second plate patterns 122P. As described above, the buffer layer 141 may be formed of an inorganic material so that the buffer layer 141 may be easily cracked or damaged during a process of stretching the display device 100. Therefore, the buffer layer 141 is not formed in an area between the plurality of first plate patterns 121P and the plurality of second plate patterns 122P. Instead, the buffer layer 141 is patterned to have a shape of the plurality of first plate patterns 121P and the plurality of second plate patterns 122P to be disposed only above the plurality of first plate patterns 121P and the plurality of second plate patterns 122P. Therefore, in the display device 100 according to the exemplary aspect of the present disclosure, the buffer layer 141 is formed only in an area overlapping the plurality of first plate patterns 121P and the plurality of second plate patterns 122P which are rigid patterns. Therefore, even though the display device 100 is bent or extended to be deformed, the damage of various components of the display device 100 may be suppressed.

A switching transistor 150 and a driving transistor 160 are disposed on the buffer layer 141.

First, a switching active layer 152 of the switching transistor 150 and the driving active layer 162 of the driving transistor 160 are disposed on the buffer layer 141. For example, the switching active layer 152 of the switching transistor 150 and the driving active layer 162 of the driving transistor 160 may be formed of an oxide semiconductor. Alternatively, the switching active layer 152 of the switching transistor 150 and the driving active layer 162 of the driving transistor 160 may be formed of amorphous silicon (a-Si), polycrystalline silicon (poly-Si), or an organic semiconductor.

The gate insulating layer 142 is disposed on the switching active layer 152 of the switching transistor 150 and the driving active layer 162 of the driving transistor 160. The gate insulating layer 142 is a layer which electrically insulates the switching gate electrode 151 from the switching active layer 152 of the switching transistor 150 and electrically insulates the driving gate electrode 161 from the driving active layer 162 of the driving transistor 160. For example, the gate insulating layer 142 may be configured by an inorganic material, for example, configured by a single layer of silicon nitride (SiNx) or silicon oxide (SiOx) or a multiple layer of silicon nitride (SiNx) or silicon oxide (SiOx), but it is not limited thereto.

The switching gate electrode 151 of the switching transistor 150 and the driving gate electrode 161 of the driving transistor 160 are disposed on the gate insulating layer 142. The switching gate electrode 151 and the driving gate electrode 161 are disposed on the gate insulating layer 142 to be spaced apart from each other. The switching gate electrode 151 overlaps the switching active layer 152 and the driving gate electrode 161 overlaps the driving active layer 162.

Each of the switching gate electrode 151 and the driving gate electrode 161 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

A first interlayer insulating layer 143 is disposed on the switching gate electrode 151 and the driving gate electrode 161. The first interlayer insulating layer 143 insulates the driving gate electrode 161 from an intermediate metal layer IM. The first interlayer insulating layer 143 may be formed of an inorganic material, similar to the buffer layer 141. For example, the first interlayer insulating layer 143 may be configured by a single layer of silicon nitride (SiNx) or silicon oxide (SiOx) which is an inorganic material or a multiple layer of silicon nitride (SiNx) or silicon oxide (SiOx), but it is not limited thereto.

An intermediate metal layer IM is disposed on the first interlayer insulating layer 143. The intermediate metal layer IM is an electrode which overlaps the gate electrode of the driving transistor 160 to form a storage capacitor. Specifically, the driving gate electrode 161 and the intermediate metal layer IM overlap each other with the first interlayer insulating layer 143 therebetween to form the storage capacitor. However, the intermediate metal layer IM overlaps the other electrode to form a storage capacitor in various manners, but is not limited thereto.

The intermediate metal layer IM may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

A second interlayer insulating layer 144 is disposed on the intermediate metal layer IM. The second interlayer insulating layer 144 insulates the switching gate electrode 151 from the switching source electrode 153 and the switching drain electrode 154 of the switching transistor 150. The second interlayer insulating layer 144 insulates the intermediate metal layer IM from the driving source electrode and the driving drain electrode 164 of the driving transistor 160. The second interlayer insulating layer 144 may be formed of an inorganic material, similar to the buffer layer 141. For example, the second interlayer insulating layer 144 may be configured by a single layer of silicon nitride (SiNx) or silicon oxide (SiOx) which is an inorganic material or a multiple layer of silicon nitride (SiNx) or silicon oxide (SiOx), but it is not limited thereto.

The switching source electrode 153 and the switching drain electrode 154 of the switching transistor 150 are disposed on the second interlayer insulating layer 144. The driving source electrode and the driving drain electrode 164 of the driving transistor 160 are disposed on the second interlayer insulating layer 144. The switching source electrode 153 and the switching drain electrode 154 of the switching transistor 150 are disposed on the same layer to be spaced apart from each other. Even though in FIG. 3, the driving source electrode of the driving transistor 160 is omitted, the driving source electrode of the driving transistor 160 is also disposed to be spaced apart from the driving drain electrode 164 on the same layer. The switching source electrode 153 and the switching drain electrode 154 are electrically connected to the switching active layer 152 through a contact hole formed in the gate insulating layer 142, the first interlayer insulating layer 143, and the second interlayer insulating layer 144. The driving source electrode and the driving drain electrode 164 are electrically connected to the driving active layer 162 through a contact hole formed in the gate insulating layer 142, the first interlayer insulating layer 143, and the second interlayer insulating layer 144. The switching drain electrode 154 of the switching transistor 150 is electrically connected to the driving gate electrode 161 of the driving transistor 160 through a contact hole formed in the first interlayer insulating layer 143 and the second interlayer insulating layer 144.

The switching source electrode 153 and the switching drain electrode 154 and the driving source electrode and the driving drain electrode 164 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

Further, in this specification, even though it is described that the driving transistor 160 has a coplanar structure, various transistors such as a staggered structure may also be used. In the present disclosure, the transistor may also be formed with a bottom gate structure, as well as the top gate structure, but is not limited thereto.

A gate pad GP, a data pad DP, and a voltage pad VP are disposed on the second interlayer insulating layer 144.

The gate pad GP is a pad which transmits a gate voltage to the plurality of sub pixels SPX. The gate pad GP is connected to the first connection line 181 through a contact hole. The gate voltage supplied from the first connection line 181 may be transmitted to the switching gate electrode 151 of the switching transistor 150 from the gate pad GP through a wiring line formed on the first plate pattern 121.

The data pad DP is a pad which transmits a data voltage to the plurality of sub pixels SPX. The data pad DP is connected to the second connection line 182 through a contact hole. The data voltage supplied from the second connection line 182 may be transmitted to the switching source electrode 153 of the switching transistor 150 from the data pad DP through a wiring line formed on the first plate pattern 121P.

The voltage pad VP is a pad which transmits a power voltage to the plurality of sub pixels SPX. The voltage pad VP is connected to the first connection line 181 through a contact hole formed in in the planarization layer 146 and the passivation layer 145. The power voltage supplied from the first connection line 181 may be transmitted to the n-electrode 174 of the LED 170 from the voltage pad VP through a second connection pattern CNT2 formed on the first plate pattern 121P.

The gate pad GP, the data pad DP, and the voltage pad VP may be formed of the same material as the switching source electrode 153, the switching drain electrode 154, and the driving drain electrode 164. For example, the gate pad GP, the data pad DP, and the voltage pad VP may be formed of any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The passivation layer 145 is formed on the switching transistor 150, the driving transistor 160, the gate pad GP, the data pad DP, and the voltage pad VP. The passivation layer 145 protects components below the passivation layer 145 from moisture and oxygen. The passivation layer 145 may be formed of an inorganic material and configured by a single layer or a double layer, but is not limited thereto.

In the meantime, the gate insulating layer 142, the first interlayer insulating layer 143, the second interlayer insulating layer 144, and the passivation layer 145 are patterned to be the same as the buffer layer 141 to be formed only in an area overlapping the plurality of first plate patterns 121. The gate insulating layer 142, the first interlayer insulating layer 143, the second interlayer insulting layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121P. However, the gate insulating layer 142, the first interlayer insulating layer 143, the second interlayer insulating layer 144, and the passivation layer 145 are patterned to have a shape of the plurality of first plate patterns 121P to be formed only above the plurality of first plate patterns 121P.

The planarization layer 146 is formed on the passivation layer 145. The planarization layer 146 planarizes upper portions of the switching transistor 150 and the driving transistor 160. The planarization layer 146 may be configured by a single layer or a plurality of layers and may be formed of an organic material. Therefore, the planarization layer 146 may also be referred to as an organic insulating layer. For example, the planarization layer 146 may be formed of an acrylic organic material, but is not limited thereto.

The planarization layer 146 may be disposed to cover top surfaces and side surfaces of the buffer layer 141, the gate insulating layer 142, the first interlayer insulating layer 143, the second interlayer insulating layer 144, and the passivation layer 145 on the plurality of first plate patterns 121P. The planarization layer 146 encloses the buffer layer 141, the gate insulating layer 142, the first interlayer insulating layer 143, the second interlayer insulating layer 144, and the passivation layer 145 together with the plurality of first plate patterns 121P. Specifically, the planarization layer 146 may be disposed to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121P.

An inclination angle of the side surface of the planarization layer 146 may be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 may have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection line 180 which is disposed to be in contact with the side surface of the planarization layer 146 is disposed with a gentle slope so that when the display device 100 is stretched, the stress generated in the connection line 180 may be reduced. Accordingly, the planarization layer 146 may supplement a step on side surfaces of the buffer layer 141, the gate insulating layer 142, the first interlayer insulating layer 143, the second interlayer insulating layer 144, and the passivation layer 145.

Further, the side surface of the planarization layer 146 has a relatively gentle slope so that the crack of the connection line 180 or separation thereof from the side surface of the planarization layer 146 may be suppressed. Accordingly, the planarization layer 146 may enhance an adhesive strength of the connection line 180 disposed on a side surface of the planarization layer 146.

Referring to FIGS. 2 to 5 and 10A, the plurality of connection lines 180 is disposed on the plurality of line patterns. The plurality of connection lines 180 refers to wiring lines which electrically connect the pads on the plurality of first plate patterns 121P and the plurality of second plate patterns 122P. The plurality of connection lines 180 is disposed on the plurality of first line patterns 121L and the plurality of second line patterns 122L. Further, the plurality of connection lines 180 is disposed on the plurality of third line patterns 123L. The plurality of connection lines 180 may extend onto the plurality of first plate patterns 121P to be electrically connected to the pad on the plurality of first plate patterns 121P. The plurality of first line patterns 121L is not disposed in an area where the plurality of connection lines 180 is not disposed, among areas between the plurality of first plate patterns 121P. Further, even though it is not illustrated in the drawing, the plurality of connection lines 180 is disposed on the plurality of second line patterns 122L to be electrically connected to a pad on the plurality of second plate patterns 122P and a pad on the plurality of first plate patterns 121P.

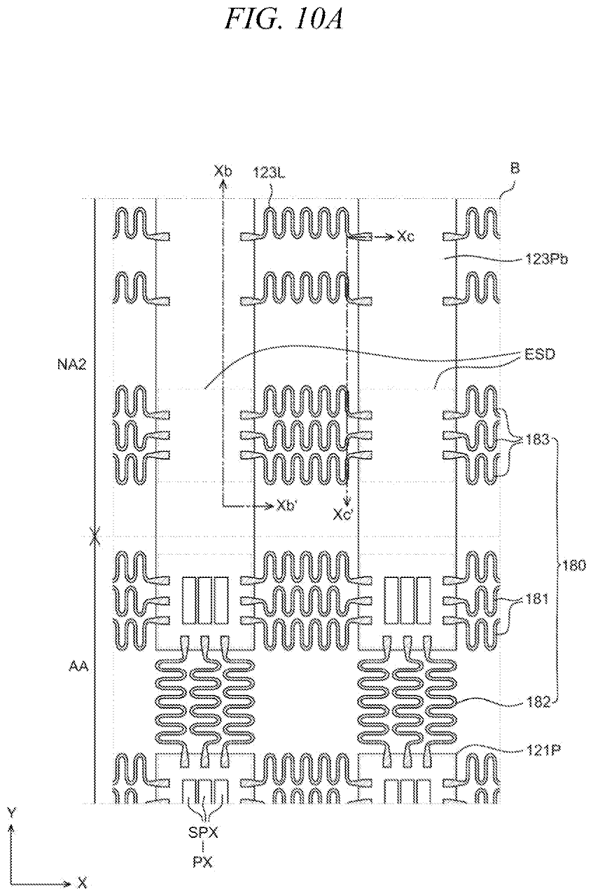

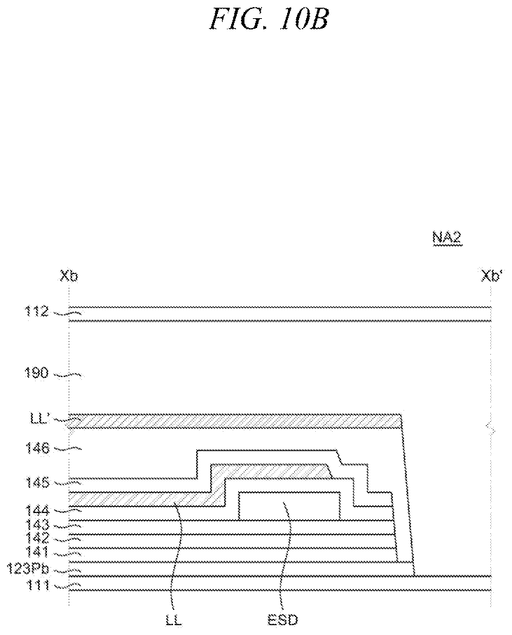

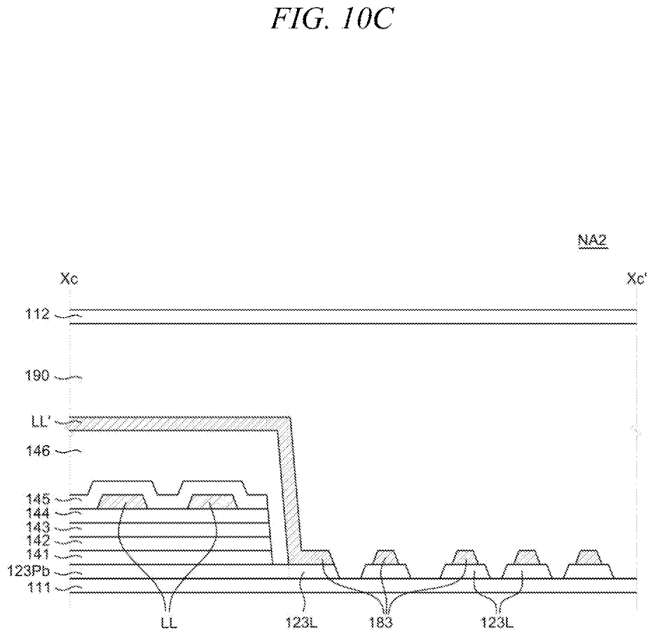

Referring to FIG. 10A, the plurality of connection lines 180 includes a plurality of first connection lines 181, a plurality of second connection lines 182 and a plurality of third connection lines 183. The first connection line 181 and the second connection line 182 are disposed between the plurality of first plate patterns 121P and the plurality of second plate patterns 122P. The plurality of third connection lines 183 is disposed between the plurality of third plate patterns 123P in the second non-active area NA2. Specifically, the first connection line 181 refers to a wiring line extending in the first direction X between the plurality of first plate patterns 121P, between the plurality of first plate patterns 121P and the plurality of second plate patterns 122P, and between the plurality of second plate patterns 122P, among the connection lines 180. The second connection line 182 refers to a wiring line extending in the second direction Y between the plurality of first plate patterns 121P and between the plurality of second plate patterns 122P, among the connection lines 180.

The plurality of connection lines 180 may be formed of a conductive material, and for example, a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a general display device, various wiring lines such as a plurality of gate lines and a plurality of data lines extend between the plurality of sub pixels in a straight line and the plurality of sub pixels is connected to one signal line. Therefore, in the general display device, various wiring lines, such as a gate line, a data line, a high potential voltage line, and a reference voltage line, extend from one side to the other side of the display device without being disconnected on the substrate.

In contrast, in the display device 100 according to the exemplary aspect of the present disclosure, various wiring lines, such as a gate line, a data line, a high potential voltage line, a reference voltage line, and an initialization voltage line having a straight line shape which are considered to be used for the general display device 100, is disposed only on the plurality of first plate patterns 121P and the plurality of second plate patterns 122P. That is, in the display device 100 according to the exemplary aspect of the present disclosure, a linear wiring line is disposed only on the plurality of first plate patterns 121P and the plurality of second plate patterns 122P.

In the display device 100 according to the exemplary aspect of the present disclosure, the pads on the two adjacent first plate patterns 121P may be connected by the first connection lines 181. For example, the plurality of first connection lines 181 electrically connects gate pads GP, data pads DP, or voltage pads VP on two adjacent first plate patterns 121P. Accordingly, the display device 100 according to the exemplary aspect of the present disclosure may include a plurality of first connection lines 181 which electrically connects various wiring lines, such as a gate line, a data line, a high potential voltage line, and a reference voltage line, between the plurality of first plate patterns 121P.

For example, the gate line extending in the first direction X may be disposed on the plurality of first plate patterns 121P and the gate pad GP may be disposed on both ends of the gate line. In this case, the plurality of gate pads GP on the plurality of first plate patterns 121P adjacent to each other in the first direction X may be connected to each other by the first connection line 181 which serves as a gate line. Therefore, the gate line disposed on the plurality of first plate patterns 121P and the first connection line 181 disposed on the first line pattern 121L may serve as one gate line. The above-described gate line may be referred to as a scan signal line. Further, wiring lines which extend in the first direction X, among all various wiring lines which may be included in the display device 100, such as an emission signal line, a low potential voltage line, and a high potential voltage line, may also be electrically connected by the first connection line 181, as described above.

As another example, a data line extending in the second direction Y may be disposed on the plurality of first plate patterns 121P and the data pad DP may be disposed on both ends of the data line. In this case, the data pad DP on the plurality of first plate patterns 121P adjacent to each other in the second direction Y may be connected to each other by the second connection line 182 which serves as a data line. Therefore, the data line disposed on the plurality of first plate patterns 121P and the second connection line 182 disposed on the first line pattern 121L may serve as one data line. Further, wiring lines which extend in the second direction Y, among all various wiring lines which may be included in the display device 100, such as a data line, a high potential voltage line, a low potential voltage line, or a reference voltage line may also be electrically connected by the second connection line 182, as described above.

Referring to FIGS. 4 and 5, the plurality of first connection lines 181 is disposed to be in contact with a top surface and a side surface of the planarization layer 146 disposed on the first plate pattern 121P. The first connection line 181 is disposed on the top surface of the first line pattern 121L and both ends thereof extend onto the first plate pattern 121L to be formed.

However, as illustrated in FIG. 6, there is no need to dispose a rigid pattern in an area where the first connection line 181 and the second connection line 182 are not disposed so that the plurality of first line patterns 121L and the plurality of second line patterns 122L are not disposed.

A connection pattern CNT is disposed on the planarization layer 146. The connection pattern CNT is a pad for electrically connecting the LED 170 to the driving transistor 160 and the low potential power line. The connection pattern CNT includes a first connection pattern CNT1 and a second connection pattern CNT2. The first connection pattern CNT1 may electrically connect the drain electrode of the driving transistor 160 and a p-electrode 175 of the LED 170 and the second connection pattern CNT2 electrically connects the low potential power line and a n-electrode 174 of the LED 170. In this case, the second connection pattern CNT2 extends from the connection line 180 which transmits the low potential power voltage to be integrally formed with the connection line 180. Therefore, when the display device 100 is driven, different voltage levels applied to the first connection pattern CNT1 and the second connection pattern CNT2 are transmitted to the n-electrode 174 and the p-electrode 175 so that the LED 170 emits light.

A bank 147 is formed on the connection pattern CNT, the connection line 180, and the planarization layer 146. The bank 147 is a component which divides adjacent sub pixels SPX. The bank 147 is disposed to cover at least a part of the connection pattern CNT, the connection line 180, and the planarization layer 146. The bank 147 may be formed of an insulating material. The bank 147 includes the black material to block wiring lines which may be visible through the active area AA. For example, the bank 147 may be formed of a carbon based mixture and specifically, include carbon black. However, it is not limited thereto and the bank 147 may be formed of a transparent insulating material. Even though in the drawing, it is illustrated that a height of the bank 147 is lower than a height of the light emitting diode 170, the present disclosure is not limited thereto and the height of the bank 147 may be equal to the height of the LED 170.

The LED 170 is disposed on the connection pattern CNT. The LED 170 includes an n-type layer 171, an active layer 172, a p-type layer 173, an n-electrode 174, and a p-electrode 175. The LED 170 of the display device 100 according to the exemplary aspect of the present disclosure has a flip-chip structure in which the n-electrode 174 and the p-electrode 175 are formed together on one surface.

A p-type layer 173 is disposed on the connection pattern CNT and the n-type layer 171 is disposed on the p-type layer. The n-type layer 171 and the p-type layer 173 are formed by doping n-type and p-type impurities into a specific material. For example, each of the n-type layer 171 and the p-type layer 173 may be layers formed by doping n type and p type impurities into a material such as gallium nitride (GaN), indium aluminum phosphide (InAlP), and gallium arsenide (GaAs). The p-type impurity may be magnesium (Mg), zinc (Zn), and beryllium (Be), and the n-type impurity may be silicon (Si), germanium (Ge), and tin (Sn), but are not limited thereto.

An active layer 172 is disposed between the n-type layer 171 and the p-type layer 173. The active layer 172 is an emission layer of the LED 170 which emits light and may be formed by a single layer or a multi-quantum well (MQW) structure, and for example, may be formed of indium gallium nitride (InGaN) or gallium nitride (GaN), but is not limited thereto.

As described above, the LED 170 of the display device 100 according to the exemplary aspect of the present disclosure may be manufactured by sequentially laminating the n-type layer 171, the active layer 172, and the p-type layer 173, and then etching a predetermined part to form the n-electrode 174 and the p-electrode 175. In this case, the predetermined part which is a space for separating the n-electrode 174 and the p-electrode 175 from each other may be etched to expose a part of the n-type layer 171. In other words, the surfaces of the LED 170 on which the n-electrode 174 and the p-electrode 175 are disposed are not flat surfaces, but have different heights.

As described above, the n-electrode 174 may be disposed on one surface of the exposed n-type layer 171 in the etched area. Further, the p-electrode 175 is disposed on one surface of the p-type layer disposed in an unetched area.

An adhesive layer AD is disposed between the LED 170 and the connection pattern CNT. The adhesive layer AD may be disposed between the n-electrode 174 and the p-electrode 175 of the LED 170 and the connection pattern CNT. The adhesive layer AD may be a conductive adhesive layer AD in which conductive balls are dispersed in an insulating base member. Therefore, when heat or a pressure is applied to the adhesive layer AD, the conductive balls are electrically connected in a portion applied with the heat or pressure to have a conductive property and an area which is not pressurized may have an insulation property. The n-electrode 174 and the p-electrode 175 are electrically connected to the connection pattern CNT by means of the adhesive layer AD. For example, after applying the adhesive layer AD on the connection pattern CNT by an inkjet method, the LED 170 is transferred onto the adhesive layer AD and the LED 170 is pressurized and heated to electrically connect the connection pattern CNT and the p-electrode 175 and the n-electrode 174. However, a part of the adhesive layer AD excluding a part of the adhesive layer AD disposed between the n-electrode 174 and the connection pattern CNT and a part of the adhesive layer AD disposed between the p-electrode 175 and the connection pattern CNT has an insulating property. Even though in FIG. 3, it is illustrated that the adhesive layers AD which cover one pair of connection patterns CNT are connected to each other, the adhesive layers AD may be separated to be disposed in each of the pair of connection patterns CNT.

Next, the upper substrate 112 is disposed on the LED 170 and the lower substrate 111. The upper substrate 112 is a substrate which supports various components disposed below the upper substrate 112. For example, the upper substrate 112 may be formed by coating and curing a material which configures the upper substrate 112 above the lower substrate 111 and the pattern layer 120.

Even though not illustrated in drawing, a polarization layer may be disposed on the upper substrate 112. The polarization layer may perform a function which polarizes light incident from the outside of the display device 100 to reduce the external light reflection. Further, an optical film other than the polarization layer may be disposed on the upper substrate 112.

A filling layer 190 is disposed between the lower substrate 111 and the upper substrate 112. The filling layer 190 may be fully filled in an empty space between the lower substrate 111 and the upper substrate 112. For example, the filling layer 190 may be configured by a curable adhesive. Specifically, the material which configures the filling layer 190 is coated on the entire surface of the lower substrate 111 and then is cured so that the filling layer 190 may be disposed between the components disposed on the upper substrate 112 and the lower substrate 111. For example, the filling layer 190 may be an optically clear adhesive (OCA) and may be configured by an acrylic adhesive, a silicon based adhesive, and an urethane based adhesive.

Hereinafter, the second non-active area NA2 and the third non-active area NA3 above the active area AA will be described in detail.

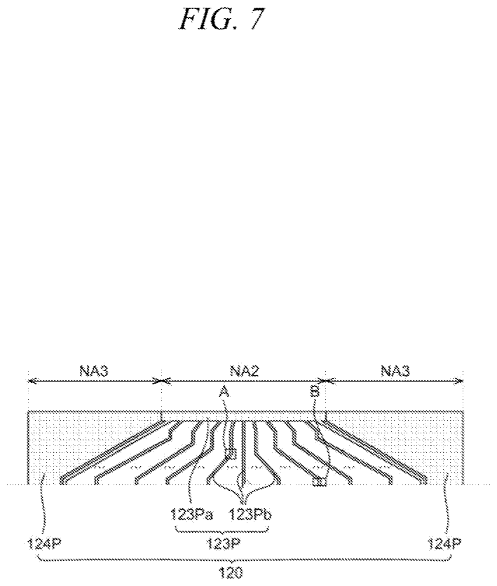

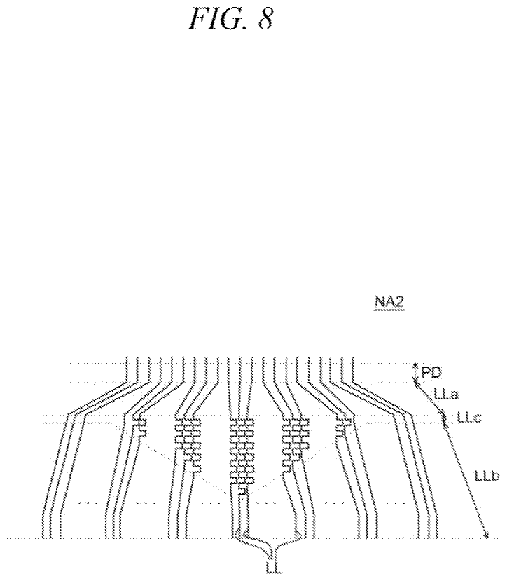

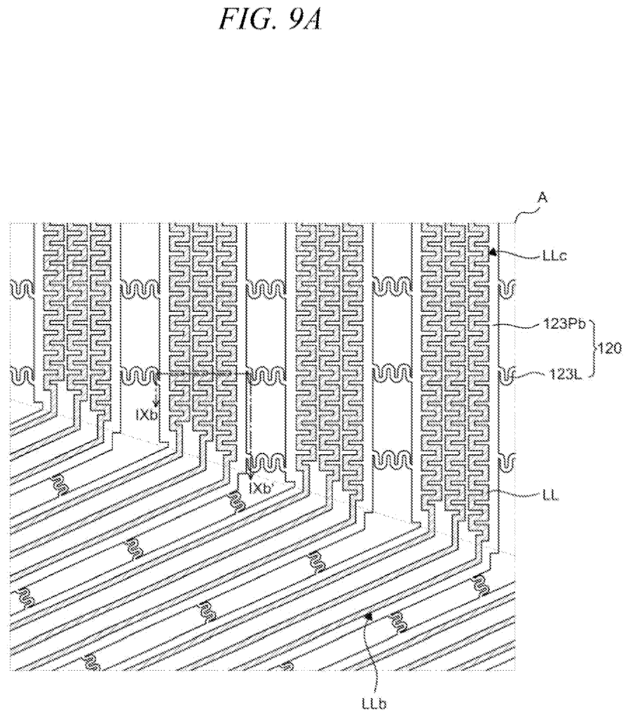

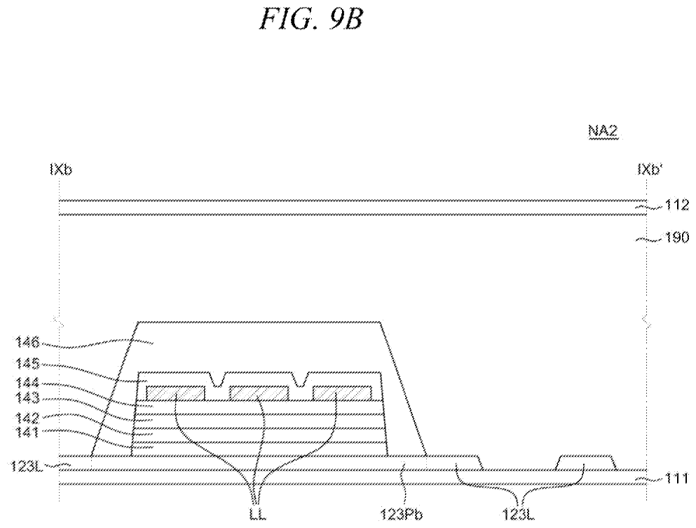

FIG. 7 is a schematic plan view of a second non-active area and a third non-active area of a display device according to an exemplary aspect of the present disclosure. FIG. 8 is a schematic plan view of a link line of a display device according to an exemplary aspect of the present disclosure. FIG. 9A is an enlarged plan view of an area A of FIG. 7. FIG. 9B is a cross-sectional view taken along IXb-IXb′ of FIG. 9A. FIG. 10A is an enlarged plan view of an area B of FIG. 7. FIG. 10B is a cross-sectional view of a display device taken along Xb-Xb′ of FIG. 10A. FIG. 10C is a cross-sectional view taken along line Xc-Xc′ of FIG. 10A. In FIG. 7, for the convenience of description, only a third plate pattern 123P and the fourth plate pattern 124P are illustrated.

Referring to FIG. 7, the pattern layer 120 further includes a third plate pattern 123P disposed in the second non-active area NA2 and a fourth plate pattern 124P disposed in the third non-active area NA3.

First, the third plate pattern 123P is disposed in the second non-active area NA2. The third plate pattern 123P is a plate pattern which supports the connection pad PD connected to the flexible film 130 and a plurality of link lines LL transmitting a signal from the connection pad PD to the active area AA. The third plate pattern 123P includes a 3-1-th plate pattern 123Pa and a plurality of 3-2-th patterns 123Pb.

A 3-1-th plate pattern 123Pa is disposed to be adjacent to an upper edge of the lower substrate 111 in the second non-active area NA2. The 3-1-th plate pattern 123Pa is a pattern layer 120 on which the plurality of connection pads PD is disposed. The 3-1-th plate pattern 123Pa may be formed as a bar shape to support the plurality of connection pads PD. The flexible film 130 is bonded onto the 3-1-th plate pattern 123Pa and the plurality of connection pads PD to supply various signals from the printed circuit board PCB and the flexible film 130 to the pixel PX.

A plurality of 3-2-th plate patterns 123Pb is disposed between the 3-1-th plate pattern 123Pa and the active area AA. The plurality of 3-2-th plate patterns 123Pb is pattern layers 120 on which the plurality of link lines LL is disposed. One end of the plurality of 3-2-th plate patterns 123Pb is connected to the 3-1-th plate patterns 123Pa and the other end is disposed to be adjacent to the active area AA. The plurality of 3-2-th plate patterns 123Pb is radially disposed. For example, a width of the 3-1-th plate pattern 123Pb is narrower than a width of the active area AA. The plurality of 3-2-th plate patterns 123Pb extending from the 3-1-th plate pattern 123Pa extends to be at least partially inclined and is evenly connected to the entire upper edge of the active area AA. For example, the plurality of 3-2-th plate pattern 123Pb is formed by an obliquely extending part and a vertically extending part.

The plurality of 3-2-th plate patterns 123Pb is disposed to be spaced apart from each other. An area in which the plurality of 3-2-th plate patterns 123Pb is disposed is an area having a rigidity and an area between the plurality of 3-2-th plate patterns 123Pb is an area having a ductility. Therefore, the plurality of 3-2-th plate patterns 123Pb is disposed to be spaced apart from each other to form a ductile area so that the second non-active area NA2 may have a stretchability.

Next, the fourth plate pattern 124P is disposed in the third non-active area NA3 on both sides of the second non-active area NA2. The power link line LL and the LOG line LOG are formed on the fourth plate pattern 124P. The fourth plate pattern 124P is connected to the 3-1-th plate pattern 123Pa to be integrally formed. However, the fourth plate pattern 124P may be formed to be separated from the 3-1-th plate pattern 123Pa, but is not limited thereto.

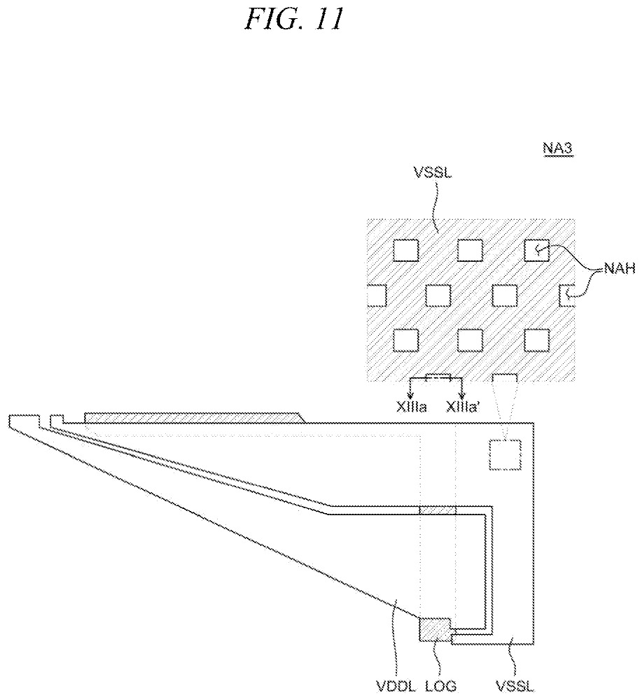

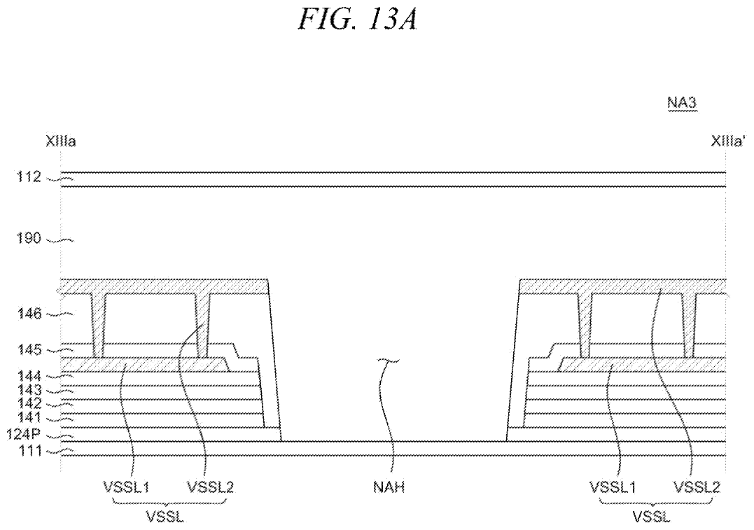

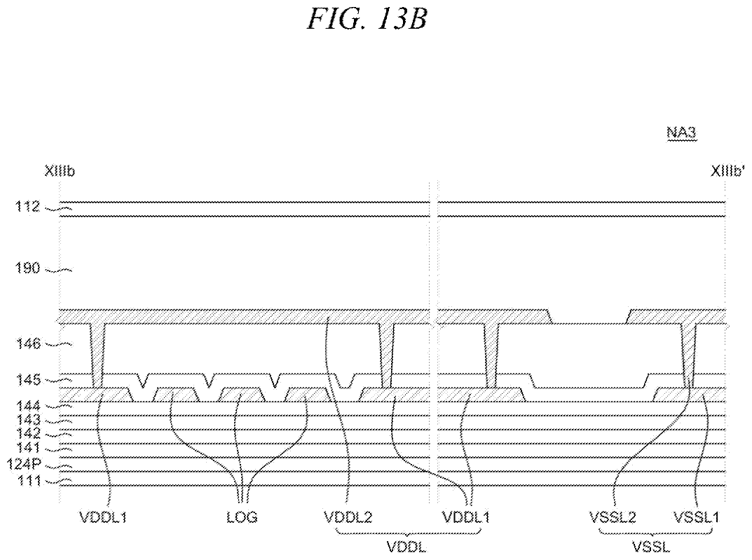

The fourth plate pattern 124P includes a plurality of holes NAH to disperse the stress during the laser lift off (LLO) process of the lower substrate 111, which will be described in more detail below with reference to FIGS. 11 and 13A.

Referring to FIGS. 8 and 9B together, a plurality of link lines LL is disposed in each of the plurality of 3-2-th plate patterns 123Pb. For example, the plurality of link lines LL is disposed on one 3-2-th plate pattern 123Pb. The plurality of link line LL is a wiring line which transmits various signals from the printed circuit board PCB and the flexible film 130 to the active area AA. Each of the plurality of link lines LL transmits a data voltage or a reference voltage to the plurality of wiring lines of the active area AA.

Referring to FIG. 9A, one end of the plurality of link lines LL is disposed on the 3-1-th plate pattern 123Pa and the other end is disposed to be adjacent to the active area AA. Each of the plurality of link lines LL extends from the connection pad PD disposed on the 3-1-th plate pattern 123Pa toward the active area AA. The plurality of link lines LL is electrically connected to the plurality of connection pads PD to be supplied with various signals from the printed circuit board PCB and the flexible film 130. The plurality of link lines LL transmits different signals from the plurality of connection pads PD to a plurality of wiring lines of the active area AA. For example, the plurality of link lines LL transmits different data voltages to each of the plurality of data lines.

n link lines LL may be disposed on one 3-2-th plate patterns 123Pb. For example, three link lines LL are disposed on one 3-2-th plate pattern 123Pb together. The plurality of link lines LL is grouped in one unit to be disposed on one 3-2-th plate patterns 123Pb. At this time, the plurality of 3-2-th plate patterns 123Pb is spaced apart from each other so that the intervals of the plurality of link lines LL may vary. For example, an interval between the link line LL disposed on the same 3-2-th plate pattern 123Pb may be narrower than an interval between the link lines LL on the 3-2-th plate patterns 123Pb which are adjacent to each other.

If the plurality of link lines LL is disposed on different 3-2-th plate patterns 123Pb, the number of 3-2-th plate patterns 123Pb is increased so that it is difficult to ensure a space for spacing the 3-2-th plate patterns 123Pb. Therefore, when the number of 3-2-th plate patterns 123B is the same as the number of the link lines LL, it is difficult to ensure the flexibility of the second non-active area NA2. Therefore, the plurality of link lines LL is grouped to be disposed on one 3-2-th plate patterns 123Pb. Therefore, in each of the plurality of 3-2-th plate patterns 123Pb, a plurality of link lines LL is disposed together so that a ductile area formed by spacing the plurality of 3-2-th plate patterns 123Pb is ensured and the flexibility of the second non-active area NA2 is improved.

Referring to FIG. 8, each of the plurality of link lines LL includes a first straight portion LLa and a second straight portion LLb and at least some link lines LL of the plurality of link lines LL further include a zigzag portion LLc.

First, each of the plurality of link lines LL includes the first straight portion LLa extending from each connection pad PD. The first straight portion LLa is a portion in which the link line LL straightly extends. A length and an extending angle of the first straight portion LLa of each of the link lines LL may vary depending on a position of the link line LL. For example, as the link line LL is closer to the third non-active area NA3, a length of the first straight portion LLa may be increased. As the link line LL is closer to the third non-active area NA3, the first straight portion LLa may extend from the connection pad PD at a larger angle.

Each of the plurality of link lines LL includes a second straight portion LLb disposed between the first straight portion LLa and the active area AA. The second straight portion LLb extends at an angle different from that of the first straight portion LLa to be evenly connected to the entire upper edge of the active area AA.

Some link lines LL among the plurality of link lines LL include a zigzag portion LLc. The zigzag portion LLc is disposed between the first straight portion LLa and the second straight portion LLb. Each of the plurality of link lines LL extends from a 3-1-th plate pattern 123Pa having a width narrower than that of the active area AA toward an upper edge of the active area AA having a larger width so that the extending angle and the entire length of each of the plurality of link lines LL may vary. When the lengths of the plurality of link lines LL vary, a signal transmitted from the plurality of link lines LL may vary due to the resistance difference. Therefore, to compensate for the length difference of the plurality of link lines LL, the zigzag portion LLc may be disposed in some link line LL. The zigzag portion LLc is a portion in which the plurality of link lines LL is disposed in a zigzag pattern so that the zigzag portion LLc is disposed to increase the entire length of the plurality of link lines LL. The length of the zigzag portion LLc may vary depending on a position of the link line LL. For example, among the plurality of link lines LL, a link line LL closer to a center of the second non-active area NA2 has a longer zigzag portion LLc.

Referring to FIGS. 9A and 9B, a plurality of insulating layers is disposed on the plurality of 3-2-th plate patterns 123Pb and the plurality of link lines LL may be disposed above any one of the plurality of insulating layers. For example, a buffer layer 141, a gate insulating layer 142, a first interlayer insulating layer 143, and a second interlayer insulating layer 144 are disposed on the 3-2-th plate pattern 123Pb and the plurality of link lines LL is disposed on the second interlayer insulating layer 114. The passivation layer 145 and the planarization layer 146 are disposed on the plurality of link lines LL to protect the link line LL.

Referring to FIGS. 10A and 10B, an electrostatic discharging circuit (ESD) is disposed in a portion of the plurality of 3-2-th plate patterns 123Pb which is adjacent to the active area AA. The electrostatic discharging circuit ESD may be disposed on the plurality of 3-2-th plate patterns 123Pb to be adjacent to the active area AA. The electrostatic discharging circuit ESD may discharge static electricity to block the static electricity. At this time, at least one insulating layer is disposed between the electrostatic discharging circuit ESD and the plurality of link lines LL to dispose the electrostatic discharging circuit ESD and the plurality of link lines LL on the 3-2-th plate pattern 123Pb.

Next, referring to FIGS. 9A and 10A, the pattern layer 120 further includes a plurality of third line patterns 123L disposed between the plurality of 3-2-th plate patterns 123Pb in the second non-active area NA2. The plurality of third line patterns 123L connects the plurality of 3-2-th plate patterns 123Pb so that during the LLO process or the stretching of the display device, the short defect of the link line LL caused by the 3-2-th plate patterns 123Pb which are in contact with each other may be suppressed. At this time, the plurality of third line patterns 123L has a wavy shape, for example, a sinusoidal shape to connect the 3-2-th patterns to each other while ensuring the stretchability of the second non-active area NA2.

Referring to FIGS. 10B and 10C, in a part of the plurality of 3-2-th plate patterns 123Pb which is adjacent to the active area AA, the plurality of link connection lines LL′ may be disposed. The link connection line LL′ electrically connects link lines LL which transmit the same signal, among the plurality of link lines LL. The link connection line LL′ may function as a kind of link line. The link connection line LL′ extends in the second direction Y on the 3-2-th plate pattern 123Pb and is electrically connected to the link lines LL which apply the same signal.

The plurality of third connection lines 183 is disposed in at least a part of the plurality of third line patterns 123L. For example, the plurality of connection lines 183 is disposed on some third line patterns 123L which are adjacent to the second straight portion LLb and the active area AA, among the plurality of third line patterns 123L. The plurality of third connection lines 183 electrically connects the plurality of link connection lines LL′ on the adjacent 3-2-th plate patterns 123Pb or the electrostatic discharging circuit ESD to each other.

For example, some link lines LL, among the plurality of link lines LL, transmit the same signal to the plurality of pixels PX. At this time, the link line LL which transmits the same signal is connected to the link connection line LL′ or the link connection line LL′ is connected to the third connection line 183 to reduce the resistance. For example, link lines LL which transmit different data voltages to each of the plurality of sub pixels SPX, among the plurality of link lines LL, may be separated from the link connection line LL′ or the third connection line 183. The link lines LL which transmit the same reference voltage and the power voltage to the plurality of sub pixels SPX, among the plurality of link lines LL, may be electrically connected to each other by the plurality of link connection lines LL′ and the plurality of third connection lines 183.

In the meantime, an end portion of the 3-2-th plate pattern 123Pb adjacent to the active area AA may be directly connected to the first plate pattern 121P of the active area AA. In this case, the link line LL on the 3-2-th plate pattern 123Pb may be directly connected to the plurality of wiring lines on the first plate pattern 121P. However, the structure illustrated in FIG. 10A is illustrative and the third plate pattern 123P and the first plate pattern 121P may be separated, but are not limited thereto.

Hereinafter, the third non-active area NA3 will be described in detail with reference to FIGS. 11 to 13B.

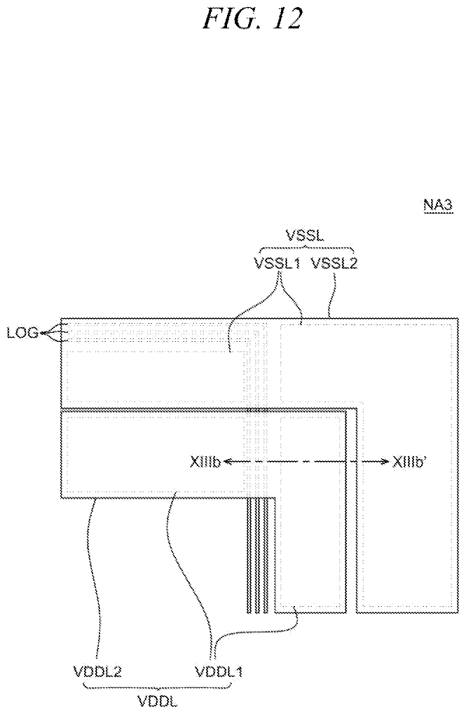

FIG. 11 is a schematic plan view of a third non-active area of a display device according to an exemplary aspect of the present disclosure. FIG. 12 is a schematic diagram of a high potential power link line, a low potential power link line, and an LOG line of a display device according to an exemplary aspect of the present disclosure. FIG. 13A is a cross-sectional view taken along line XIIIa-XIIIa′ of FIG. 11. FIG. 13B is a cross-sectional view taken along line XIIIb-XIIIb′ of FIG. 12. For the convenience of description, in FIG. 11, a substantial planar structure of a second high potential power link line VDDL2, a second low potential power link line VSSL2, and an LOG line LOG is illustrated. Further, in FIG. 12, the entire structure of a high potential power link line VDDL, a low potential power link line VSSL, and an LOG line LOG is schematically illustrated.

Referring to FIGS. 11 to 13B, in the third non-active area NA3, a fourth plate pattern 124P and a high potential power link line VDDL, a low potential power link line VSSL, and an LOG line LOG on the fourth plate pattern 124P are disposed. Further, in the third non-active area NA3, a plurality of holes NAH which passes through the fourth plate pattern 124P is formed.

First, referring to FIGS. 11 and 13A, in the third non-active area NA3, a plurality of holes NAH which passes through the fourth plate pattern 124P, the high potential power link line VDDL, and the low potential power link line VSSL is formed. For example, the plurality of holes NAH may be formed to pass through the fourth plate pattern 124P and the insulating layer, the high potential power link line VDDL, and the low potential power link line VSSL on the fourth plate pattern 124P and relieve a stress of the third non-active area NA3 which does not include a separate ductile area, during the LLO process. The plurality of holes NAH may be formed to pass through the fourth plate pattern 124P, the plurality of insulating layers on the fourth plate pattern 124P, and the high potential power link line VDDL and the low potential power link line VSSL between the plurality of insulating layers. Therefore, in an area corresponding to the plurality of holes NAHY, only the lower substrate 111, the filling layer 190, and the upper substrate 112 are disposed and the third non-active area NA3 may partially have a flexibility in the plurality of holes NAH.

Referring to FIGS. 11, 12. And 13B, the high potential power link line VDDL is disposed between the second non-active area NA2 and the low potential power link line VSSL. The high potential power link line VDDL transmits a high potential power voltage to the high potential power line of the active area AA. The high potential power link line VDDL includes a plurality of first high potential power link lines VDDL1 and a second high potential power link line VDDL2. The plurality of first high potential power link lines VDDL1 is disposed to be spaced apart from each other with the LOG line LOG therebetween. The second high potential power link line VDDL2 electrically connects the plurality of first high potential power link lines VDDL1 to each other to reduce the entire resistance of the high potential power link line VDDL.

The plurality of insulating layers is disposed on the fourth plate pattern 124P and the plurality of first high potential power link lines VDDL1 is disposed above any one of the plurality of insulating layers. For example, a buffer layer 141, a gate insulating layer 142, a first interlayer insulating layer 143, and a second interlayer insulating layer 144 are disposed on the fourth plate pattern 124P and the plurality of first high potential power link lines VDDL1 is disposed on the second interlayer insulating layer 144.

The second high potential power link line VDDL2 is disposed on a layer different from that of the plurality of first high potential power link lines VDDL1. For example, the passivation layer 145 and the planarization layer 146 are disposed on the plurality of first high potential power link lines VDDL1 and the second high potential power link line VDDL2 is disposed on the planarization layer 146. The second high potential power link line VDDL2 is electrically connected to the plurality of first high potential power link lines VDDL1 through the contact holes formed in the planarization layer 146 and the passivation layer 145.

The low potential power link line VSSL includes a plurality of first low potential power link lines VSSL1 and a second low potential power link line VSSL2. The low potential power link line VSSL transmits a low potential power voltage to the low potential power line of the active area AA. The low potential power link line VSSL includes a plurality of first low potential power link lines VSSL1 and a second low potential power link line VSSL2. The plurality of first low potential power link lines VSSL1 is disposed to be spaced apart from each other with the LOG line LOG therebetween. The second low potential power link line VSSL2 electrically connects the plurality of first low potential power link lines VSSL1 to each other to reduce the entire resistance of the low potential power link line VSSL.

The plurality of insulating layers is disposed on the fourth plate pattern 124P and the plurality of first low potential power link line VSSL1 is disposed above any one of the plurality of insulating layers. For example, a buffer layer 141, a gate insulating layer 142, a first interlayer insulating layer 143, and a second interlayer insulating layer 144 are disposed on the fourth plate pattern 124P and the plurality of first low potential power link lines VSSL1 is disposed on the second interlayer insulating layer 144.

The second low potential power link line VSSL2 is disposed on a layer different from that of the plurality of first low potential power link lines VSSL1. For example, the passivation layer 145 and the planarization layer 146 are disposed on the plurality of first low potential power link lines VSSL1 and the second low potential power link line VSSL2 is disposed on the planarization layer 146. The second low potential power link line VSSL2 is electrically connected to the plurality of first low potential power link lines VSSL1 through the contact holes formed in the planarization layer 146 and the passivation layer 145.

The LOG line LOG is disposed between the plurality of first high potential power link lines VDDL1 and the plurality of first low potential power link lines VSSL1. The LOG line is a wiring line which transmits various signals to the gate driver GD disposed in the first non-active area NA1. The plurality of first high potential power link lines VDDL1 and the plurality of first low potential power link lines VSSL1 may be disposed to be spaced apart from each other with the LOG line LOG therebetween. For example, the LOG line LOG may be disposed between the second interlayer insulating layer 144 and the passivation layer 145. The LOG line LOG extends to the first non-active area NA1 to transmit a gate low voltage, a gate high voltage, a start signal, and a clock signal for driving the gate driver GD to the gate driver on the second plate pattern 122P.

The manufacturing process of the display device 100 according to the exemplary aspect of the present disclosure may be performed in a state in which a pattern layer 120 is disposed on a glass substrate and a sacrificial layer. When the process of forming the upper substrate 112 on the pattern layer 120 is completed, an LLO process of irradiating laser to a lower portion of the glass substrate to separate the pattern layer 120 and the glass substrate may be performed. Thereafter, the lower substrate 111 is attached to the lower portion of the pattern layer 120 to complete the manufacturing process of the display device 100. At this time, the upper substrate 122 formed in a state in which the glass substrate is attached is a flexible substrate so that a size thereof may be deformed during the process of removing the glass substrate.

For example, in the related art, both the second non-active area and the third non-active area in which the plurality of link lines is disposed are formed as rigid areas. That is, a plate pattern which covers the second non-active area and the third non-active area is formed so that the second non-active area and the third non-active area cannot be stretched. In this case, during the process of separating the pattern layer from the glass substrate, the upper substrate is partially contracted so that the stretching rate difference between the active area and the first non-active area which may be easily stretched and the second non-active area and the third non-active area which are hardly stretched is caused. The active area and the first non-active area which may be easily stretched may disperse the stress generated during the contracting process, but in the second non-active area and the third non-active area which are hardly stretched, it is difficult to disperse the contraction stress so that the plurality of link lines may be damaged. Further, the stretchability of the second non-active area and the third non-active area above the active area is low so that a stretching direction of the display device may be restricted.

Therefore, in the display device 100 according to the exemplary aspect of the present disclosure, the plurality of link lines LL is not disposed with a uniform interval, but the plurality of link lines LL is grouped to be disposed in the unit of groups so that the ductile area between the plurality of link lines LL may be ensured. The stretchability is given to the link line LL which is easily damaged due to the contraction stress during the LLO process, specifically, the second non-active area NA2 in which the link line LL is disposed, so that the damage of the plurality of link lines LL during the LLO process may be minimized. At this time, when the plurality of link lines LL is disposed with a constant interval, it may be difficult to ensure a space between the plurality of 3-2-th plate patterns 123Pb. At this time, n link lines LL are grouped in the unit of groups and the link lines LL are disposed with a minimum interval in the group to form a space between the groups and a space between the 3-2-th plate patterns 123Pb. Therefore, the second non-active area NA2 has a flexibility to relieve the stress during the LLO process and minimize the damage of the plurality of link lines LL.

In the display device 100 according to the exemplary aspect of the present disclosure, a plurality of holes NAH is formed in the third non-active area NA3 to relieve the stress of the third non-active area NA3. The high potential power link line VDDL and the low potential power link line VSSL disposed in the third non-active area NA3 is not an elongated line, but may be disposed in the entire non-active area NA3 in the form of a plate. When a plurality of holes NAH is formed in the third non-active area NA3, the fourth pattern 124P and the high potential power line VDDL and the low potential power link line VSSL disposed above the fourth plate pattern 124P may be formed with a mesh shape. Therefore, during the LLO process, a stress applied to the third non-active area NA3 may be relieved by the mesh type fourth plate pattern 124P.

The exemplary aspects of the present disclosure may also be described as follows:

According to an aspect of the present disclosure, a display device includes a lower substrate which includes an active area, a first non-active area on both sides of the active area, a second non-active area above the active area, and a third non-active area on both sides of the second non-active areas; a plurality of plate patterns disposed in the active area, the first non-active area, the second non-active area, and the third non-active area; a plurality of line patterns which is disposed between the plurality of plate patterns in the active area, the first non-active area, and the second non-active area; and a plurality of link lines disposed on the plurality of plate patterns in the second non-active area.

The plurality of plate patterns may include a plurality of first plate patterns which is disposed in the active area and is spaced apart from each other; a plurality of second plate patterns which is disposed in the first non-active area and is spaced apart from each other; a plurality of third plate patterns which is disposed in the second non-active area and has the plurality of link lines disposed therein; and a fourth plate pattern disposed in the third non-active area.

The plurality of line patterns may include a plurality of first line patterns disposed between the plurality of first plate patterns; a plurality of second line patterns disposed between the plurality of second plate patterns; and a plurality of third line patterns disposed between the plurality of third plate patterns.

The plurality of third plate patterns may include a 3-1-th plate pattern which is disposed to be adjacent to an edge of the lower substrate in the second non-active area; and a plurality of 3-2-th plate patterns which extends to the active area from the 3-1-th plate pattern and is spaced apart from each other, and the plurality of third line patterns may be disposed between the plurality of 3-2-th plate patterns.

At least a portion of the plurality of 3-2-th plate patterns may extend obliquely to be radially disposed.

N link lines may be disposed in each of the plurality of 3-2-th plate patterns.

The plurality of link lines may include a straight portion which straightly extends along an extending direction of the plurality of 3-2-th plate patterns, at least some of the plurality of link lines may further include a zigzag portion which is connected to the straight portion and may extend in a zigzag shape, and lengths of the zigzag portions in the plurality of link lines may be different.

The display device may further include a plurality of connection pads disposed on the 3-1-th plate pattern. Each of the plurality of connection pads may be electrically connected to the plurality of link lines.

The display device may further include a plurality of first connection lines which extends in a first direction and is disposed on the plurality of first line patterns and the plurality of second line patterns; a plurality of second connection lines which extends in a second direction which is different from the first direction and is disposed on the plurality of first line patterns and the plurality of second line patterns; and a plurality of third connection lines disposed on the plurality of third line patterns.

The display device may further include a link connection line which is disposed on the plurality of 3-2-th plate patterns and is electrically connected to some link line among the plurality of link lines. The link connection lines disposed in the plurality of 3-2-th plate patterns may be electrically connected to each other through the plurality of third connection lines.

The display device may further include an electrostatic discharging circuit disposed on the plurality of 3-2-th plate patterns. The electrostatic discharging circuits disposed on the plurality of 3-2-th plate patterns may be electrically connected to each other through the plurality of third connection lines.

The display device may further include a high potential power link line disposed on the fourth plate pattern; a low potential power link line which is disposed on the fourth plate pattern and is spaced apart from the high potential power link line; and a line on glass (LOG) line which is disposed on the fourth plate pattern and is spaced apart from the high potential power link line and the low potential power link line.

The high potential power link line may include a plurality of first high potential power link lines spaced apart from each other; and a second high potential power link line which is disposed on the plurality of first high potential power link lines and electrically connects the plurality of first high potential power link lines.

The low potential power link line may include a plurality of first low potential power link lines which is disposed on the same layer as the plurality of first high potential power link lines and is spaced apart from each other; and a second low potential power link line which is disposed on the same layer as the second high potential power link line and electrically connects the plurality of first low potential power link lines.

The LOG line may be disposed between the plurality of first high potential power link lines and the plurality of first low potential power link lines.

The display device may further include a plurality of insulating layers which is disposed between the fourth plate pattern and the plurality of first high potential power link lines and between the plurality of first high potential power link lines and the plurality of second high potential power link lines; and a plurality of holes which passes through the fourth plate pattern, the plurality of high potential power link lines, the plurality of low potential power link lines, and the plurality of insulating layers in the third non-active area.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. All the technical concepts in the equivalent scope of the present disclosure should be construed as falling within the scope of the present disclosure.

What is claimed is:

1. A display device, comprising:
a lower substrate which includes an active area, a first non-active area disposed on both sides of the active area, a second non-active area disposed above the active area, and a third non-active area disposed on both sides of the second non-active areas;
a plurality of plate patterns disposed in the active area, the first non-active area, the second non-active area, and the third non-active area;
a plurality of line patterns disposed between the plurality of plate patterns in the active area, the first non-active area, and the second non-active area; and
a plurality of link lines disposed on the plurality of plate patterns in the second non-active area.

2. The display device according to claim 1, wherein the plurality of plate patterns includes:
a plurality of first plate patterns disposed in the active area and spaced apart from each other;
a plurality of second plate patterns disposed in the first non-active area and spaced apart from each other;
a plurality of third plate patterns disposed in the second non-active area and having the plurality of link lines disposed therein; and
a fourth plate pattern disposed in the third non-active area.

3. The display device according to claim 2, wherein the plurality of line patterns includes:
a plurality of first line patterns disposed between the plurality of first plate patterns;
a plurality of second line patterns disposed between the plurality of second plate patterns; and
a plurality of third line patterns disposed between the plurality of third plate patterns.

4. The display device according to claim 3, wherein the plurality of third plate patterns includes:
a 3-1-th plate pattern disposed to be adjacent to an edge of the lower substrate in the second non-active area; and
a plurality of 3-2-th plate patterns extending to the active area from the 3-1-th plate pattern and is spaced apart from each other, wherein the plurality of third line patterns disposed between the plurality of 3-2-th plate patterns.

5. The display device according to claim 4, wherein at least a portion of the plurality of 3-2-th plate patterns extends obliquely to be radially disposed.

6. The display device according to claim 4, wherein n link lines are disposed in each of the plurality of 3-2-th plate patterns.

7. The display device according to claim 4, wherein the plurality of link lines includes a straight portion which straightly extends along an extending direction of the plurality of 3-2-th plate patterns, and
wherein at least some of the plurality of link lines further includes a zigzag portion which is connected to the straight portion and extends in a zigzag shape, and lengths of the zigzag portions in the plurality of link lines are different.

8. The display device according to claim 4, further comprising a plurality of connection pads disposed on the 3-1-th plate pattern,
wherein each of the plurality of connection pads is electrically connected to the plurality of link lines.

9. The display device according to claim 4, further comprising:
a plurality of first connection lines extending in a first direction and is disposed on the plurality of first line patterns and the plurality of second line patterns;
a plurality of second connection lines extending in a second direction which is different from the first direction and is disposed on the plurality of first line patterns and the plurality of second line patterns; and
a plurality of third connection lines disposed on the plurality of third line patterns.

10. The display device according to claim 9, further comprising a link connection line disposed on the plurality of 3-2-th plate patterns and is electrically connected to some link line among the plurality of link lines,
wherein the link connection lines disposed in the plurality of 3-2-th plate patterns are electrically connected to each other through the plurality of third connection lines.

11. The display device according to claim 9, further comprising an electrostatic discharging circuit disposed on the plurality of 3-2-th plate patterns,
wherein the electrostatic discharging circuits disposed on the plurality of 3-2-th plate patterns are electrically connected to each other through the plurality of third connection lines.

12. The display device according to claim 3, further comprising:
a plurality of high potential power link line disposed on the fourth plate pattern;
a plurality of low potential power link line disposed on the fourth plate pattern and spaced apart from the high potential power link line; and
a line on glass (LOG) line disposed on the fourth plate pattern and spaced apart from the high potential power link line and the low potential power link line.

13. The display device according to claim 12, wherein the plurality of high potential power link line includes:
a plurality of first high potential power link lines spaced apart from each other; and
a plurality of second high potential power link line disposed on the plurality of first high potential power link lines and electrically connecting the plurality of first high potential power link lines.

14. The display device according to claim 13, wherein the plurality of low potential power link line includes:
a plurality of first low potential power link lines disposed on the same layer as the plurality of first high potential power link lines and is spaced apart from each other; and
a second low potential power link line disposed on the same layer as the second high potential power link line and electrically connecting the plurality of first low potential power link lines.

15. The display device according to claim 14, wherein the LOG line is disposed between the plurality of first high potential power link lines and the plurality of first low potential power link lines.

16. The display device according to claim 14, further comprising:
a plurality of insulating layers disposed between the fourth plate pattern and the plurality of first high potential power link lines and between the plurality of first high potential power link lines and the plurality of second high potential power link lines; and
a plurality of holes passing through the fourth plate pattern, the plurality of high potential power link lines, the plurality of low potential power link lines, and the plurality of insulating layers in the third non-active area.
